(19) United States
(12) Patent Application Publication
(10) Pub. No.: US 2023/0024122 A1
(43) Pub. Date: Jan. 26, 2023

(54) SMALL-SIZE MILLIMETER WAVE ON-CHIP 90-DEGREE 3DB COUPLERS BASED ON SOLENOID STRUCTURES

(71) Applicant: Mobix Labs, Inc., Irvine, CA (US)

(72) Inventors: Oleksandr Gorbachov, Irvine, CA (US); Lisette L. Zhang, Irvine, CA (US)

(21) Appl. No.: 17/653,976

(22) Filed: Mar. 8, 2022

Related U.S. Application Data
(60) Provisional application No. 63/158,137, filed on Mar. 8, 2021.

(51) Int. Cl. H01P 5/18; H01L 23/66

(52) U.S. Cl. CPC H01P 5/186; H01L 23/66; H01L 2223/6627; H01L 2223/6688

(57) ABSTRACT

A 90-degree, 3 dB coupler has an input port, an isolated port, a first output port, and a second output port. A plurality of solenoid structures are arranged in a parallel, spaced relationship. A first group of the interconnects bridge the solenoid structures of a first set that define a first contiguous connection from the input port to the first output port. A second group of interconnects bridge the solenoid structures of a second set that define a second contiguous connection from the isolated port to the second output port. A third group of interconnects bridge the solenoid structures of a third set that define a third contiguous connection from the isolated port to the second output port. The solenoid structures are each unique to a respective one of the first set, second set, and the third set.

### CROSS-REFERENCE TO RELATED APPLICATIONS

This application relates to and claims the benefit of U.S. Provisional Application No. 63/158,137, filed Mar. 8, 2021 and entitled “SMALL-SIZE MM-WAVE ON-CHIP 90DEGREE 3DB COUPLERS BASED ON SOLENOID STRUCTURES”, the disclosure of which is wholly incorporated by reference in its entirety herein.

### STATEMENT RE: FEDERALLY SPONSORED RESEARCH/DEVELOPMENT

Not Applicable

### BACKGROUND

### 1. Technical Field

The present disclosure relates generally to radio frequency (RF) circuit components and couplers specifically, and more particularly, to small-size millimeter wave (mmWave) on-chip 90-degree 3 dB couplers based on solenoid structures.

### 2. Related Art

Couplers are passive devices utilized to couple a part of the transmission power on one signal path to another signal path by a predetermined amount, and 3 dB 90-degree couplers in particular are widely used in RF circuits and systems. For example, quadrature power splitter/combiners in power amplifiers and low noise amplifiers utilize 3 dB 90-degree couplers, as do local oscillator (LO) or main signal distribution systems in image-reject transmitters and receivers, and so forth. In its simplest form, as its nomenclature suggests, a 3 dB 90-degree coupler operates to split an RF signal applied to one port into two output chains with half the input signal power at each, with the phase difference across the split ports is 90 degrees. The key parameters of the coupler are the amplitude balance and phase balance between the split ports, with conventional implementations typically having specifications of less than 1 dB and less than 5 degrees, respectively. Conventional couplers, however, have a fairly large footprint in semiconductor die implementations.

Multiple splitter structures may be used, while the smallest footprints may be achieved with Lange couplers, which have four ports (input port, coupled port, direct port, isolated port) and generally defined by interdigitated transmission or metal microstrip lines. The minimum dimension of the coupled strip line is equal to one quarter wavelength. The main coupling over the strip lines, which define the amplitude balance, is strongly dependent on the spacing between the metal strips. Furthermore, the surrounding area around the microstrip lines must be free of other metal structures, because otherwise, coupling and amplitude balance may be significantly changed. The high dielectric constant of semiconductor substrates such as silicon or gallium arsenide, typically greater than 10, permits a substantial reduction in the maximum footprint of the entire coupler. There has been a continuous effort in the art to decrease the footprint further, with various zig-zag or meander type configurations being one effective approach to this end. Additionally, the placement of coupled traces on different metal layers has also contributed to overall footprint reduction.

The high dielectric constant of the semiconductor substrate also assists in the reduction in footprint in configurations where the coupler is placed on the top of the substrate while the bottom of the substrate is operating as an RF ground plane. The other dimensions of the coupler are still comparatively large, which results in increased production costs of the overall semiconductor die.

In part due to the miniaturization trends in the electronics and semiconductor fields, flip-chip configurations where the semiconductor die is disposed on multiple carriers are popular. However, in a flip-chip configuration, the advantage provided by the high dielectric constant of semiconductor substrates may be diminished, as the RF ground plane is typically positioned on the die carrier with the coupler structure being placed in between. The dielectric constant of this intermediate material is understood to be substantially less than 10, and more commonly 3 to 4.

Accordingly, there is a need in the art for reducing the footprint of the coupler in flip-chip configurations. Increasing the operating bandwidth of the couplers is a high design priority for multiple applications, and while the reduction of absolute power loss is important, amplitude balance is more critical. Coupling between the metal traces is understood to be limited by specific geometries depending on fabrication technology, so it would be desirable for coupler configurations that mitigate the foregoing constraints. It would be preferable for such configurations to be implemented across a wide range of semiconductor technologies, as well as in low temperature co-fired ceramic (LTCC) and laminate structures.

### BRIEF SUMMARY

The embodiments of the present disclosure include 3 dB 90-degree couplers based on solenoid structures that are suitable for millimeter wave (mmWave) applications. The structures employ additional capacitive coupling via conductive strips, patches, and stubs across multiple layers. The different shapes and sizes of the capacitively coupled structures allow control of frequency dependence of amplitude and phase over a wide frequency range. Accordingly, the couplers of the present disclosure may be implemented in different semiconductor technologies as well as in low-temperature co-fired ceramic and laminate structures.

According to various embodiments, a coupler has an input port, an isolated port, a first output port, and a second output port. The coupler may include a plurality of solenoid structures arranged in a parallel, spaced relationship. There may also be a plurality of interconnects. A first group of the interconnects may bridge the solenoid structures of a first set that define a first contiguous connection from the input port to the first output port. A second group of interconnects may bridge the solenoid structures of a second set that define a second contiguous connection from the isolated port to the second output port. A third group of interconnects may bridge the solenoid structures of a third set that define a third contiguous connection from the isolated port to the second output port. The solenoid structures may each being unique to a respective one of the first set, second set, and the third set.

The present disclosure will be best understood accompanying by reference to the following detailed description when read in conjunction with the drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1A is a cross-sectional view of one exemplary flip-chip configuration;

FIG. 1B is a cross-sectional view of another exemplary flip-chip configuration;

FIG. 2 is a top plan view of a 90-degree 3 dB coupler in accordance with a first embodiment of the present disclosure;

FIG. 3A is a perspective view showing the top side of the first embodiment of the coupler;

FIG. 3B is a perspective view showing the bottom side of the first embodiment of the coupler;

FIG. 3C is a magnified perspective view showing additional details of the layered structure of the first embodiment of the coupler from the bottom side thereof;

FIG. 3D is a magnified perspective view showing additional details of the layered structure of the first embodiment of the coupler from the top side thereof;

FIG. 4 is graph plotting the S-parameters for the simulated performance parameters of the first embodiment of the coupler;

FIG. 5 is a graph plotting the simulated phase shift performance over a frequency sweep of the first embodiment of the coupler;

FIG. 6 is a top plan view of a second embodiment of the coupler that incorporates lateral compensating conductive strip;

FIG. 7A a perspective view showing the top side of the second embodiment of the coupler;

FIG. 7B a perspective view showing the bottom side of the second embodiment of the coupler;

FIG. 7C is a magnified perspective view showing additional details of the layered structure of the second embodiment of the coupler from the bottom side thereof;

FIG. 7D is a magnified perspective view showing additional details of the layered structure of the second embodiment of the coupler from the top side thereof;

FIG. 8 is graph plotting the S-parameters for the simulated performance parameters of the second embodiment of the coupler;

FIG. 9 is a graph plotting the simulated phase shift performance over a frequency sweep of the second embodiment of the coupler;

FIG. 10A is a perspective view showing the top side of a third embodiment of the coupler which incorporates capacitive coupled ports;

FIG. 10B is a detailed perspective view with an enlarged view of the capacitive coupled ports in the third embodiment of the coupler;

FIG. 11 is graph plotting the S-parameters for the simulated performance parameters of the third embodiment of the coupler;

FIG. 12 is a graph plotting the simulated phase shift performance over a frequency sweep of the third embodiment of the coupler;

FIG. 13 is a magnified perspective view of a fourth embodiment of the coupler that incorporates a compensating conductive patch and capacitive coupled ports;

FIG. 14 is graph plotting the S-parameters for the simulated performance parameters of the fourth embodiment of the coupler;

FIG. 15 is a graph plotting the simulated phase shift performance over a frequency sweep of the fourth embodiment of the coupler;

FIG. 16 is a top plan view of a fifth embodiment of the coupler with capacitive coupled ports but without a compensating conductive strip;

FIG. 17 is graph plotting the S-parameters for the simulated performance parameters of the fifth embodiment of the coupler;

FIG. 18 is a graph plotting the simulated phase shift performance over a frequency sweep of the fifth embodiment of the coupler;

FIG. 19 is a top plan view of a sixth embodiment of the coupler that incorporates a compensating conductive patch of alternative dimensions;

FIG. 20 is a magnified perspective view of the coupler according to the sixth embodiment of the present disclosure;

FIG. 21 is graph plotting the S-parameters for the simulated performance parameters of the sixth embodiment of the coupler;

FIG. 22 is a graph plotting the simulated phase shift performance over a frequency sweep of the sixth embodiment of the coupler;

FIG. 23 is a top plan view of a seventh embodiment of the coupler with longitudinally oriented compensating conductive strips;

FIG. 24 is a magnified perspective view of the seventh embodiment of the coupler;

FIG. 25 is graph plotting the S-parameters for the simulated performance parameters of the seventh embodiment of the coupler; and

FIG. 26 is a graph plotting the simulated phase shift performance over a frequency sweep of the seventh embodiment of the coupler.

### DETAILED DESCRIPTION

The present disclosure encompasses various embodiments of a 3 dB 90-degree coupler that avoids conventional design constraints with the use of an additional, different type of capacitive coupling using conductive strips, patches, and stubs on different layer. It is contemplated that adjusting the size and shape of the capacitively coupled metal structures will permit the control of frequency dependence on amplitude and phase of coupled ports over a wide frequency range.

The detailed description set forth below in connection with the appended drawings is intended as a description of the several presently contemplated embodiments of the 3 dB 90-degree coupler and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second, left, right, top, and bottom and the like are used solely to distinguish one from another entity without necessarily requiring or implying any actual such relationship or order between such entities. Various features of the embodiments of the present disclosure make reference to dielectric and metal layers, as well as dimensions thereof. These particulars are presented in the context of a 28 nm CMOS semiconductor process, but it will be appreciated that other processes may be substituted, with modifications to the dimensions and other specific parameters being within the purview of those having ordinary skill in the art.

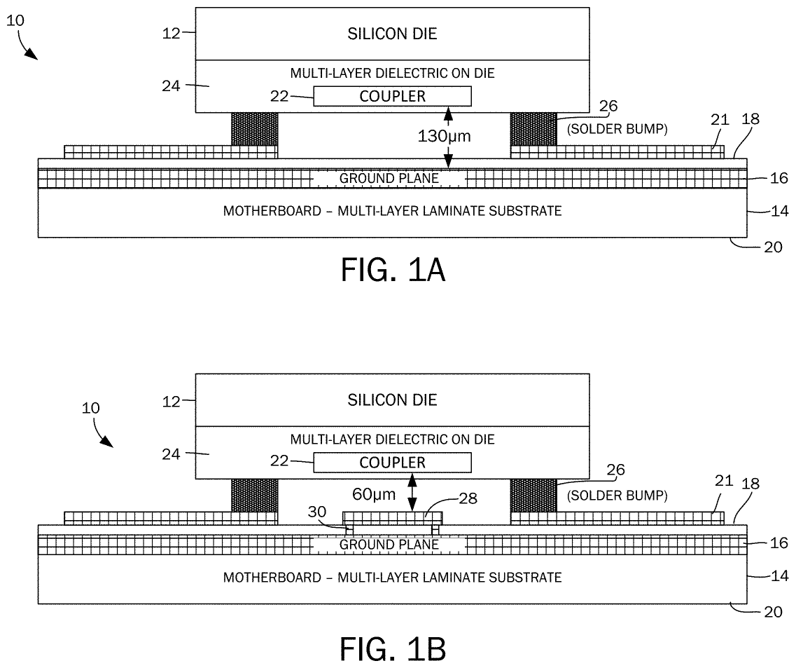

With reference to FIG. 1A, one implementation of a flip-chip configuration 10 is shown, which generally includes a semiconductor die 12 that is mounted on to a motherboard 14 or other multi-layer laminate substrate. In further detail, the motherboard 14 includes a ground plane 16 embedded therein and unexposed on a top surface 18 or a bottom surface 20 of the motherboard 14. The top surface 18 of the motherboard 14 includes conductive traces 21 that are a part of the circuit interconnecting the semiconductor die 12 to other components. According to various embodiments of the present disclosure, a coupler 22 is incorporated into the semiconductor die 12 and may be embedded within a multi-layer dielectric 24. The semiconductor die 12, in turn, is mounted on to the motherboard 14 with solder bumps 26. In this configuration, the spacing between the coupler 22 and the ground plane 16 may be 130 μm.

FIG. 1B illustrates another implementation of a flip-chip configuration 10. Similar to the first implementation discussed above, the semiconductor die 12 includes the multi-layer dielectric 24 within which the coupler 22 is embedded. The semiconductor die 12 is attached to the conductive traces on the motherboard 14 with the solder bumps 26. This motherboard 14 likewise includes the ground plane 16 but includes an exposed ground plane 28 on the top surface 18. The exposed ground plane 28 is electrically contiguous with the ground plane 16 by way of vias 30. In this configuration, the spacing between the coupler 22 and the exposed ground plane 28 may be 60 μm.

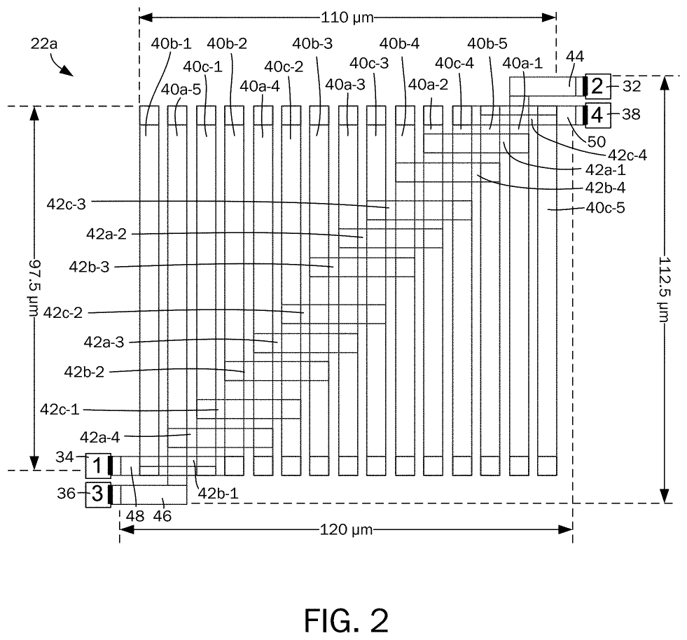

With reference to FIG. 2, a first embodiment of a 90-degree 3 dB coupler 22a has an input port 32, an isolated port 34, a first output port 36, and a second output port 38. The input port 32 is understood to be connected to a signal source, and the coupler 22a splits such signal and outputs a signal attenuated by 3 dB at both the first output port 36 and the second output port 38. The phase of the signal at the first output port 36 is understood to be shifted by approximately 0 degrees, while the phase of the signal at the second output port 38 is understood to be shifted by approximately 90 degrees.

The coupler 22a includes a plurality of solenoid structures 40 that are arranged in a parallel, spaced relationship, as well as a plurality of interconnects 42. As will be illustrated in greater detail, the interconnects 42 may define an integral and unitary structure with the solenoid structures 40 or at least a part thereof, but will be referred to separately as a consequence of having a configuration that are not common with those shared between all of the solenoid structures 40. Along these lines, each of the solenoid structures 40 may be comprised of multiple elements as will be described in further detail below, but may be referenced as a combination for the sake of convenience. It will be appreciated by those having ordinary skill in the art that the solenoid structures 40 and the interconnects 42 may be variously configured with alternatives that meet the same functions being deemed to be within the scope of the present disclosure.

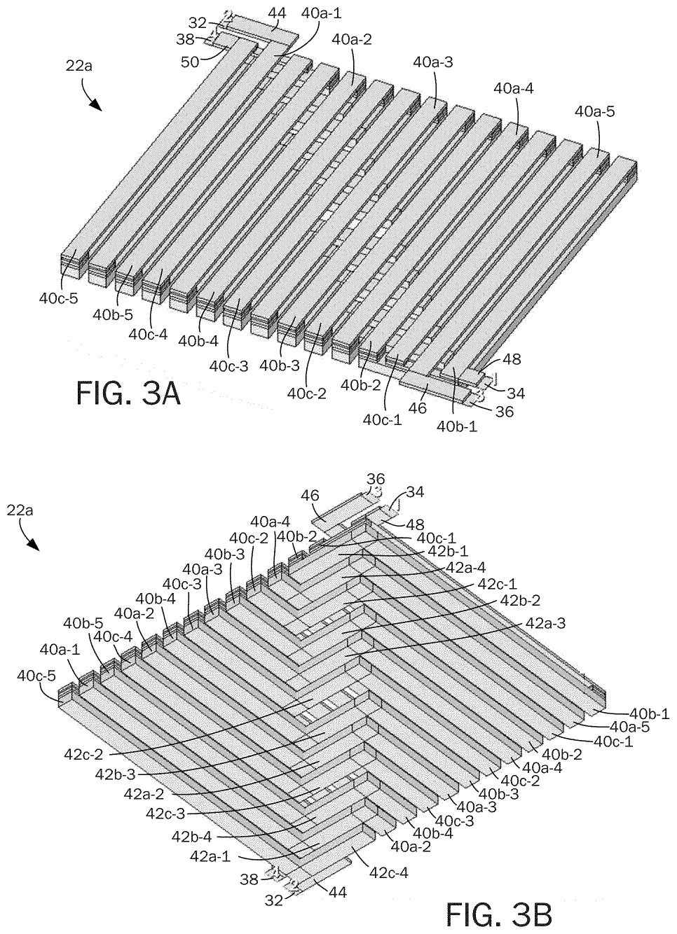

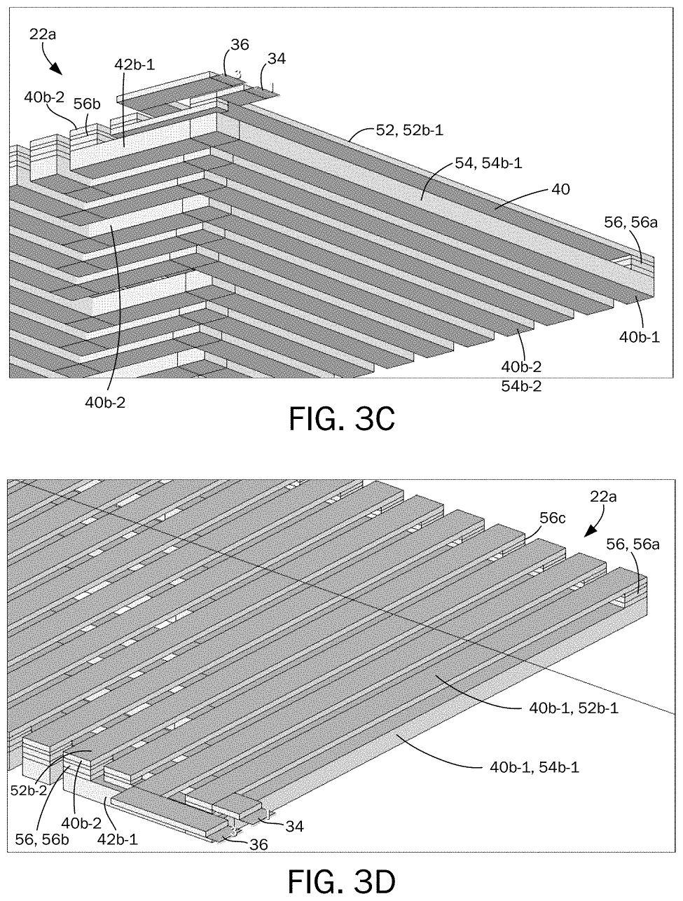

With additional reference to FIGS. 3A and 3B, a first group of interconnects 42a are understood to bridge the couplings strips of a first set 40a that define a first contiguous connection from the input port 32 and the first output port 36. In further detail, in the first set of solenoid structures 40a, there is a first solenoid structure 40a-1 that is connected to a second solenoid structure 40a-2 over a first interconnect 42a-1. The second solenoid structure 40a-2 is then connected to a third solenoid structure 40a-3 over a second interconnect 42a-2. The third solenoid structure 40a-3 is connected to a fourth solenoid structure 40a-4 over a third interconnect 42a-3. Lastly, the fourth solenoid structure 40a-4 is connected to a fifth solenoid structure 40a-5 over a fourth interconnect 42a-4. The first solenoid structure 40a-1 is connected to an input port connector strip 44 that is in turn connected to the input port 32. At the opposite end in the contiguous first set of solenoid structures 40a, there may be an first output port connector strip 46 that is connected to the first output port 36.

The coupler 22a also includes a second group of interconnects 42b that bridge the solenoid structures of a second set 40b that define a second contiguous connection from the isolated port 34 to the second output port 38. In the second set of solenoid structures 40b, there is a first solenoid structure 40b-1 that is connected to a second solenoid structure 40b-2 over a first interconnect 42b-1. The second solenoid structure 40b-2 is then connected to a third solenoid structure 40b-3 over a second interconnect 42b-2. The third solenoid structure 40b-3 is connected to a fourth solenoid structure 40b-4 over a third interconnect 42b-3. The fourth solenoid structure 4ba-4 is connected to a fifth solenoid structure 40b-5 over a fourth interconnect 42b-4. The first solenoid structure 40b-1 is connected to an isolated port connector strip 48 that is in turn connected to the isolated port 33. At the opposite end in the contiguous second set of solenoid structures 40b, there may be an second output port connector strip 50 that is connected to the second output port 38.

There may be a separate conductive path from the isolated port 34 to the second output port 38 that is defined by a third set 40c of solenoid structures. There may accordingly be a third group of interconnects 42c that bridge such solenoid structures. In further detail, there is a first solenoid structure 40c-1 that is connected to a second solenoid structure 40c-2 over a first interconnect 42c-1. The second solenoid structure 40c-2 is then connected to a third solenoid structure 40c-3 over a second interconnect 42c-2. The third solenoid structure 40c-3 is connected to a fourth solenoid structure 40c-4 over a third interconnect 42c-3. The fourth solenoid structure 40c-4 is connected to a fifth solenoid structure 40c-5 over a fourth interconnect 42c-4. The first solenoid structure 40c-1 is connected to the isolated port connector strip 48 that is in turn connected to the isolated port 33. At the opposite end in the contiguous second set of solenoid structures 40c, the fifth solenoid structure 40c-5 is connected to the second output port connector strip 50, which in turn is connected to the second output port 38.

As shown, each of the solenoid structures 40 are unique to either the first set, the second set or the third sets. Furthermore, adjacent ones of the solenoid structures 40 are of different sets. For example, the first solenoid structure 40a-1 is part of the first set, while the one adjacent to the right, the fifth solenoid structure 40c-5, is part of the third set, and the one adjacent to the left, the fifth solenoid structure 40b-5, is part of the second set. Likewise, adjacent ones of the interconnects 42 are also of different groups. The first interconnect 42a-1, for example, is a part of the first group and associated with the first set of solenoid structures 40a, with the fourth interconnect 42c-4 that is immediately adjacent/above is a part of the third group associated with the third set of solenoid structures 40c. Furthermore, the fourth interconnect 42b-4 that is immediately adjacent/below the first interconnect 42a-1 is a part of the second group associated with the second set of solenoid structures 40b. The foregoing relationships as among the solenoid structures 40 as well as among the interconnects are applicable across the entirety of the coupler 22.

Referring now to FIGS. 3C and 3D, the solenoid structures 40 may each be defined by a thin strip part 52 as well as a thick strip part 54. The thin strip part 52 is understood to have an configuration as was described above for a given one of the solenoid structures 40. The thick strip part 54 is understood to be vertically offset from the thin strip part 52 with a via 56. The thick strip part 54 extends to the junction with the particular interconnect 42 that bridges over to the next successive solenoid structure 40 in the set. For example, a thin strip part 52b-1 of the first solenoid structure 40b-1 of the second set is connected on one end to the isolated port 34. The opposite end is connected to a first via 56a, which in turn is connected to a thick strip part 54b-1 of the first solenoid structure 40b-1(in the second set). The thick strip part 54b-1 extends back to the opposite end until reaching the junction with the second interconnect 42b-1, which crosses over to the second solenoid structure 40b-2(in the second set). Another via 56b connects the second interconnect 42b-1 to the thin strip part 52b-2 of the second solenoid structure 40b-2. The thin strip part 52b-2 extends back to the opposite end, where it is connected to a corresponding thick strip part 54b-2 over another via 56c. The thick strip part 54b-2 traverses back to the junction point with the second interconnect 42b-2. This configuration is repeated for each of the sets of solenoid structures 40 and interconnects 42. Each of the interconnects 42 in the coupler 22 are understood to be oriented perpendicularly relative to the solenoid structures 40. The thick strip part 54 of each solenoid structure 40 may be integral or have a unitary structure with, or at least coplanar with the interconnects 42 to which it is connected.

The first embodiment of the coupler 22 may have an overall footprint of approximately 120 μm×112.5 μm. In further detail, each of the solenoid structures 40 may have a width of 5 μm, and separated from adjacent ones by 2.5 μm. The foregoing overall dimensions are understood to encompass the additional widths and lengths of various connector strips. Specifically, the width of 120 μm for the coupler 22 includes the width of the solenoid structures 40 and separation distances, plus the length of the first output port connector strip 46/isolated port connector strip 48, as well as the length of the second output port connector strip 50/input port connector strip 44. The length of 112.5 μm is understood to encompass the additional width of the first output port connector strip 46 as well as the width of the input port connector strip 44, plus the length of the solenoid structures 40, which according to one embodiment is 97.5 μm. The thin strip part 52 may be implemented on an M6 layer of the semiconductor die, and have a thickness of 1 μm, while the thick strip part 54 may be implemented on an AP layer of the semiconductor die with a thickness of 3 μm. Each of the connector strips, that is, the input port connector strip 44, the first output port connector strip 46, the isolated port connector strip 48, and the second output port connector strip 50 may have a thickness of 1 μm.

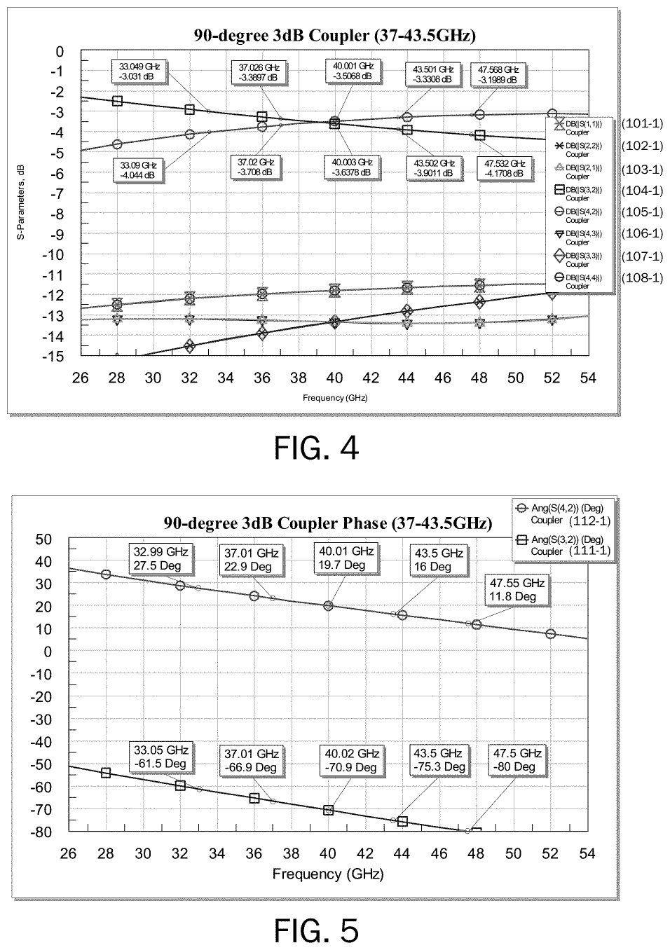

Referring now to the graphs of FIGS. 4 and 5, the simulated performance of the first embodiment of the coupler 22a will be considered. FIG. 4 in particular plots the simulated scattering parameters (S-Parameters over a frequency sweep between 26 to 54 GHz (37 to 43.5 GHz is referenced to case in which amplitude imbalance is below 1 dB), with a first plot 101-1 showing the reflection coefficient/return loss S11 at the input port 32, and a second plot 102-1 showing the reflection coefficient S22 at the isolated port 34. A third plot 103-1 shows the insertion loss S21 between the isolated port 34 and the input port 32, and a fourth plot 104-1 the shows the insertion loss S31 between the second output port 38 and the input port 32. Similarly, a fifth plot 105-1 shows the insertion loss S41 between the first output port 36 and the input port 32. A sixth plot 106-1 shows the isolation between the first output port 36 and the second output port 38 (S43). A seventh plot 107-1 shows the output reflection coefficient S33 of the second output port 38, and an eighth plot 108-1 shows the output reflection coefficient S44 of the first output port 36.

The graph of FIG. 5 illustrates the simulated phase shift performance of the first embodiment of the coupler 22a over the same frequency sweep of 26 to 54 GHz. A first plot 111-1 shows the phase shift that gets applied to the input signal on the input port 32 when output to the first output port 36, and a second plot 112-1 shows the phase shift at the second output port 38.

The following table 1 summarizes the simulated difference in output signal power from the first output port 36 and the second output port 38, as well as the output signal phase from the same, across selected operating frequencies. Furthermore, the average power loss at either of the output ports 36, 38 for each of the selected operating frequencies are presented. As can be seen, there may be a small amplitude imbalance of less than 0.57 dB, as well as a phase imbalance across the full 37-43.5 GHz operating frequency range. However, the power loss in the split chains is understood to be less than 0.62 dB.

TABLE 1

| F (GHz) | 33 GHz | 37 GHz | 40 GHz | 43.5 GHz | 47.5 GHz |
|---|---|---|---|---|---|
| Delta OUT, dB | 1.0 | 0.32 | 0.13 | 0.57 | 1.0 |
| Delta Angle, | 89.0 | 89.8 | 90.6 | 91.3 | 91.8 |
| degree | | | | | |
| Average Loss, dB | 3.54 | 3.55 | 3.57 | 3.62 | 3.68 |

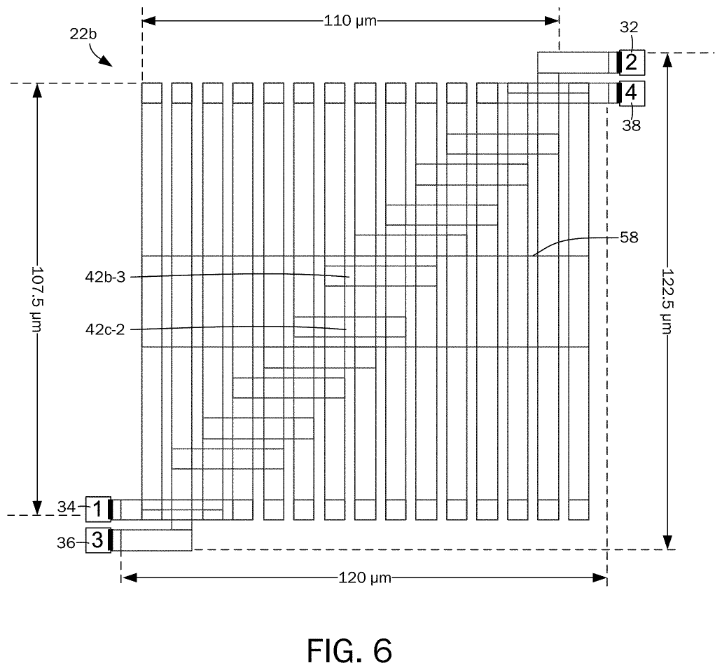

FIG. 6 shows a second embodiment of a 90-degree 3 dB coupler 22b with the input port 32, the isolated port 34, the first output port 36, and the second output port 38. The input port 32 is connected to a signal source, and the coupler 22b splits such signal and outputs a signal attenuated by 3 dB at both the first output port 36 and the second output port 38. The phase of the signal at the first output port 36 is shifted by approximately 0 degrees, while the phase of the signal at the second output port 38 is shifted by approximately 90 degrees. The second embodiment of the coupler 22b shares much of the same structure as the first embodiment of the coupler 22a discussed above, and so for the sake of brevity, the details will be omitted.

In general, the coupler 22b includes a plurality of solenoid structures 40 that are arranged in a parallel, spaced relationship, as well as a plurality of interconnects 42. Again, there are multiple groups of interconnects that bridge the solenoid structures 40 of a different sets that define contiguous connections from the input port 32 to the first output port 36 and from the isolated port to the second output port.

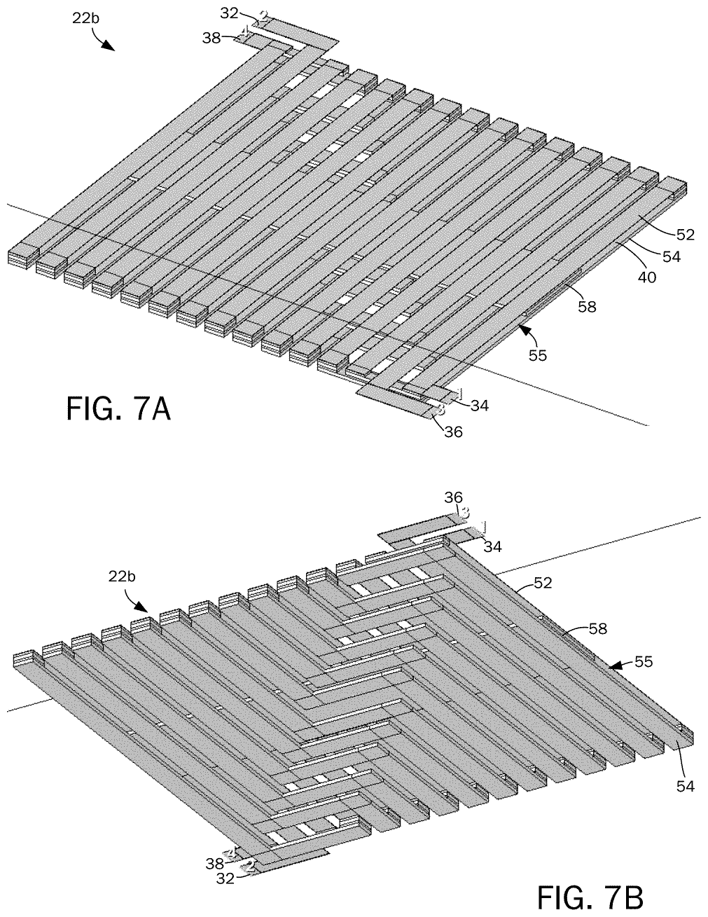

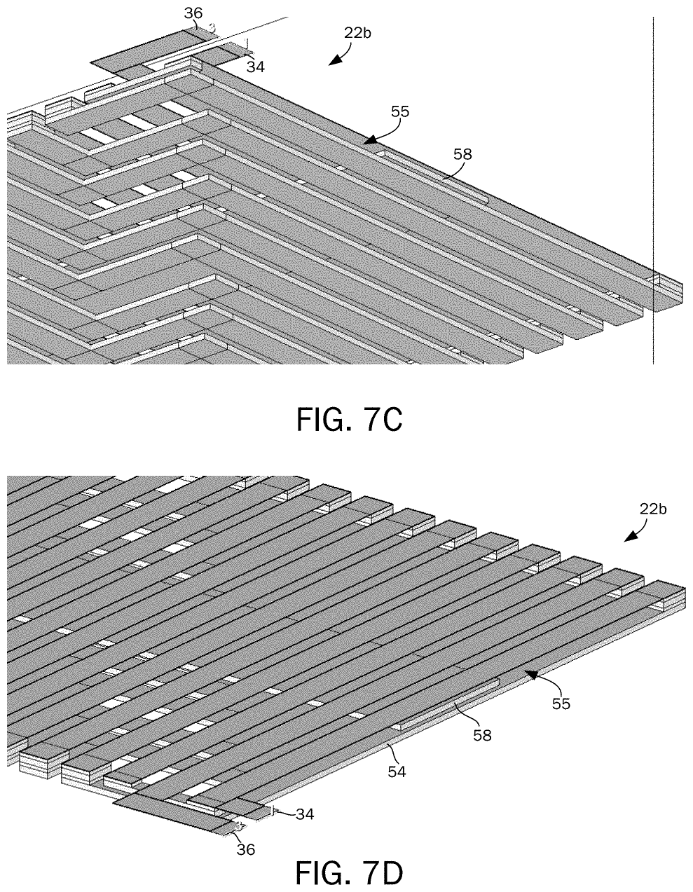

With reference to FIGS. 7A, 7B. 7C, and 7D, the solenoid structures 40 may be comprised of an upper thin strip part 52 and a lower thick strip part 54. The each of the thin strip parts 52 and each of the thick strip parts 54 are separated or vertically offset from each other, and thus an interior space 55 is defined. According to the second embodiment, the coupler 22b incorporates a compensating conductive strip 58 that extends laterally across all of the solenoid structures 40, and disposed within the interior space 55 between the thin strip parts 52 and the thick strip parts 54. The compensating conductive strip 58 may have a width of approximately 22.5 μm, a length of 110 μm when oriented in the direction perpendicular top the solenoid structures 40. As shown in the top plan view of FIG. 6, the compensating conductive strip 58 may be disposed in the central region of the solenoid structures 40 overlapping the third interconnect 42b-3 for the second set of solenoid structures 40b, and the second interconnect 42c-2 for the third set of solenoid structures 40c.

The second embodiment of the coupler 22b may have an overall footprint of approximately 120 μm×122.5 μm, on the account of longer solenoid structures 40 to accommodate the compensating conductive strip 58. Each of the solenoid structures 40 may have a width of 5 μm, and separated from adjacent ones by 2.5 μm as in the first embodiment 22a, similar to the first embodiment of the coupler 22b. The thin strip part 52 may be implemented on an M5 layer of the semiconductor die, and have a thickness of 0.1 μm, while the thick strip part 54 may be implemented on an M7 layer of the semiconductor die with a thickness of 1 μm. The compensating conductive strip 58 may be implemented on the M6 layer of the semiconductor die, with a thickness of approximately 1 μm. Each of the connector strips 44, 46, 48, and 50 may have a thickness of 1 μm.

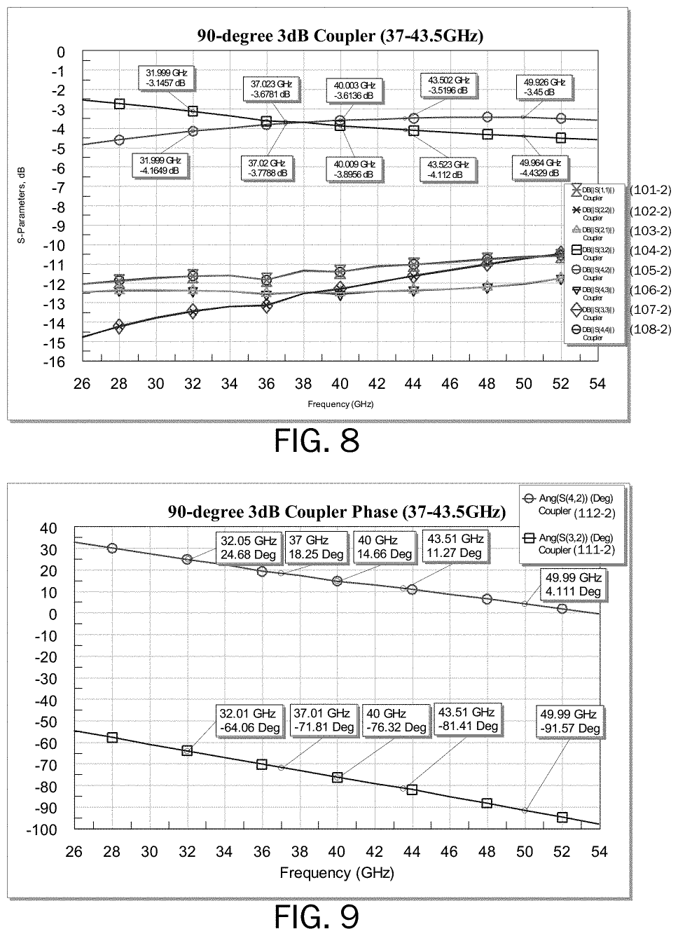

The graphs of FIGS. 8 and 9 illustrate the simulated performance of the second embodiment of the coupler 22b. FIG. 8 in particular plots the simulated scattering parameters (S-Parameters) over a frequency sweep between 26 to 54 GHz, with a first plot 101-2 showing the reflection coefficient/return loss S11 at the input port 32, and a second plot 102-2 showing the reflection coefficient S22 at the isolated port 34. A third plot 103-2 shows the insertion loss S21 between the isolated port 34 and the input port 32, and a fourth plot 104-2 the shows the insertion loss S31 between the second output port 38 and the input port 32. Similarly, a fifth plot 105-2 shows the insertion loss S41 between the first output port 36 and the input port 32. A sixth plot 106-2 shows the isolation between the first output port 36 and the second output port 38 (S43). A seventh plot 107-2 shows the output reflection coefficient S33 of the second output port 38, and an eighth plot 108-2 shows the output reflection coefficient S44 of the first output port 36.

The graph of FIG. 9 illustrates the simulated phase shift performance of the second embodiment of the coupler 22b over the same frequency sweep of 26 to 54 GHz. A first plot 111-2 shows the phase shift that gets applied to the input signal on the input port 32 when output to the first output port 36, and a second plot 112-2 shows the phase shift at the second output port 38.

The following table 2 summarizes the simulated difference in output signal power from the first output port 36 and the second output port 38, as well as the output signal phase from the same, across selected operating frequencies. Furthermore, the average power loss at either of the output ports 36, 38 for each of the selected operating frequencies are presented. There may be a small amplitude imbalance of less than 0.59 dB, as well as a phase imbalance across the full 37-43.5 GHz operating frequency range. The power loss in the split chains is understood to be less than 0.82 dB.

TABLE 2

| F (GHz) | 32 GHz | 37 GHz | 40 GHz | 43.5 GHz | 50 GHz |
|---|---|---|---|---|---|
| Delta OUT, dB | 1.0 | 0.1 | 0.28 | 0.59 | 1.0 |
| Delta Angle, | 88.74 | 90 | 91 | 92.7 | 95.68 |
| degree | | | | | |
| Average Loss, dB | 3.66 | 3.73 | 3.76 | 3.82 | 3.94 |

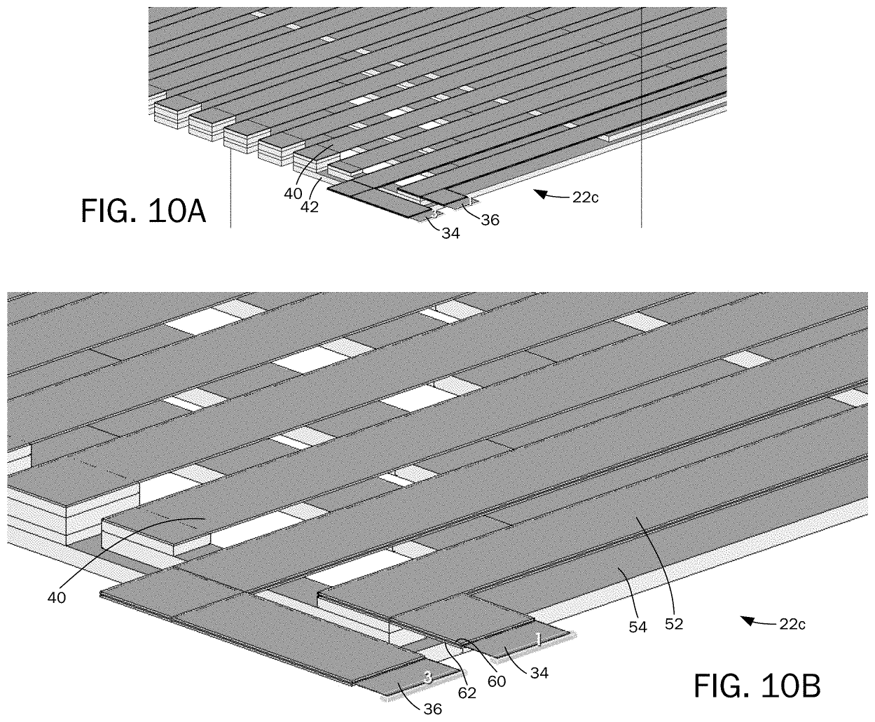

FIGS. 10A. and 10B illustrate portions of an alternative third embodiment of a 90-degree 3 dB coupler 22c. Like the other two embodiments, there is an input port, an isolated port, a first output port, and the second output port, but only the isolated port 34 and the first output port 36 are shown. The third embodiment of the coupler 22c shares much of the same structure as the second embodiment of the coupler 22b, and so for the sake of brevity, the details will be omitted.

Like the earlier discussed embodiments, the coupler 22c includes a plurality of solenoid structures 40 that are arranged in a parallel, spaced relationship, as well as a plurality of interconnects 42. Again, there are multiple groups of interconnects 42 that bridge the solenoid structures 40 of a different sets that define contiguous connections from the input port 32 to the first output port 36 and from the isolated port to the second output port. The solenoid structures 40 may be comprised of the upper thin strip part 52 and a lower thick strip part 54. The third embodiment of the coupler 22 likewise incorporates the compensating conductive strip 58 between the thin strip parts 52 and the thick strip parts 54.

The third embodiment of the coupler 22c, however, incorporates capacitively coupled ports. In further detail, the connector strips that interconnect the input port 32, the isolated port 34, and the output ports 36, 38 to corresponding solenoid structures 40 as detailed above, may each be comprised of a top conductive layer and a bottom conductive layer, with the conductive layer of the port being sandwiched between. As shown in FIG. 10B, the isolated port 34 is connected to the isolated port connector strip 48. The isolated port connector strip 48, in turn, may be implemented with two separate semiconductor die metal layers M4 and M5, with a top layer 60 being on the M4 layer and a bottom layer 62 being on the M5 layer. Both the top layer 60 and the bottom layer 62 may be 0.1 μm. The same configuration may be repeated for the first output port 36, as well as the second output port (not shown) and the input port (not shown). The thick strip part 54 of the solenoid structures 40 may be implemented on the M6 layer, with a thickness of 1 μm.

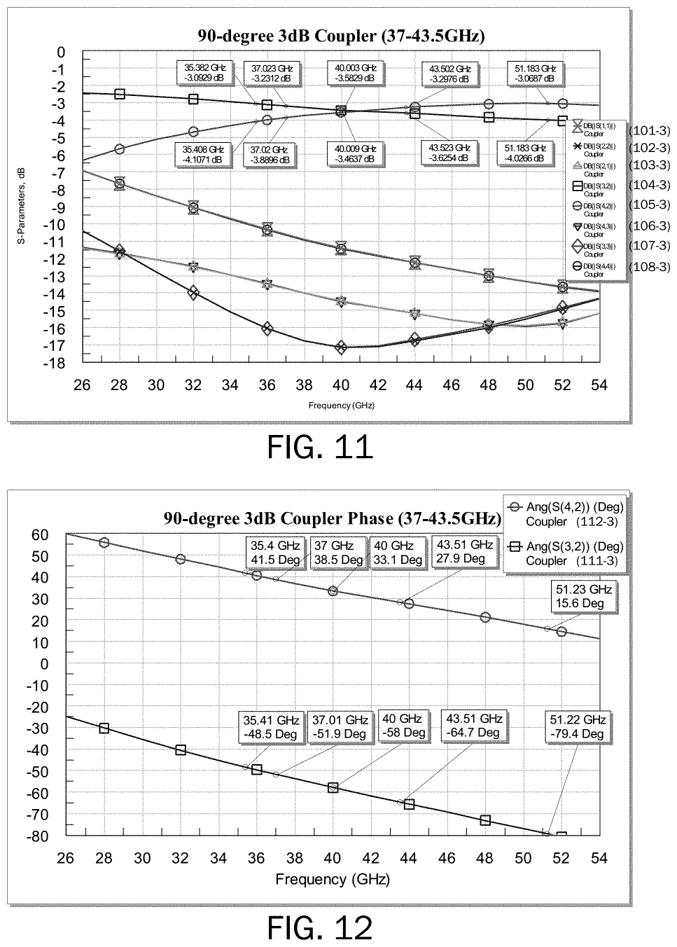

The graphs of FIGS. 11 and 12 illustrate the simulated performance of the third embodiment of the coupler 22c. FIG. 11 plots the simulated scattering parameters (S-Parameters) over a frequency sweep between 26 to 54 GHz, with a first plot 101-3 showing the reflection coefficient/return loss S11 at the input port 32, and a second plot 102-3 showing the reflection coefficient S22 at the isolated port 34. A third plot 103-3 shows the insertion loss S21 between the isolated port 34 and the input port 32, and a fourth plot 104-3 the shows the insertion loss S31 between the second output port 38 and the input port 32. Similarly, a fifth plot 105-3 shows the insertion loss S41 between the first output port 36 and the input port 32. A sixth plot 106-3 shows the isolation between the first output port 36 and the second output port 38 (S43). A seventh plot 107-3 shows the output reflection coefficient S33 of the second output port 38, and an eighth plot 108-3 shows the output reflection coefficient S44 of the first output port 36. It is contemplated that the capacitive coupling of the ports improves return loss as well as isolation.

The graph of FIG. 12 illustrates the simulated phase shift performance of the third embodiment of the coupler 22c over the same frequency sweep of 26 to 54 GHz. A first plot 111-3 shows the phase shift that gets applied to the input signal on the input port 32 when output to the first output port 36, and a second plot 112-3 shows the phase shift at the second output port 38.

The following table 3 summarizes the simulated difference in output signal power from the first output port 36 and the second output port 38, as well as the output signal phase from the same, across selected operating frequencies. Furthermore, the average power loss at either of the output ports 36, 38 for each of the selected operating frequencies are presented.

TABLE 3

| F (GHz) | 35.4 GHz | 37 GHz | 40 GHz | 43.5 GHz | 51.2 GHz |
|---|---|---|---|---|---|
| Delta OUT, dB | 1.0 | 0.66 | 0.12 | 0.33 | 1.0 |
| Delta Angle, degree | 90.0 | 90.4 | 91.1 | 92.6 | 95.0 |
| Average Loss, dB | 3.6 | 3.56 | 3.52 | 3.46 | 3.55 |

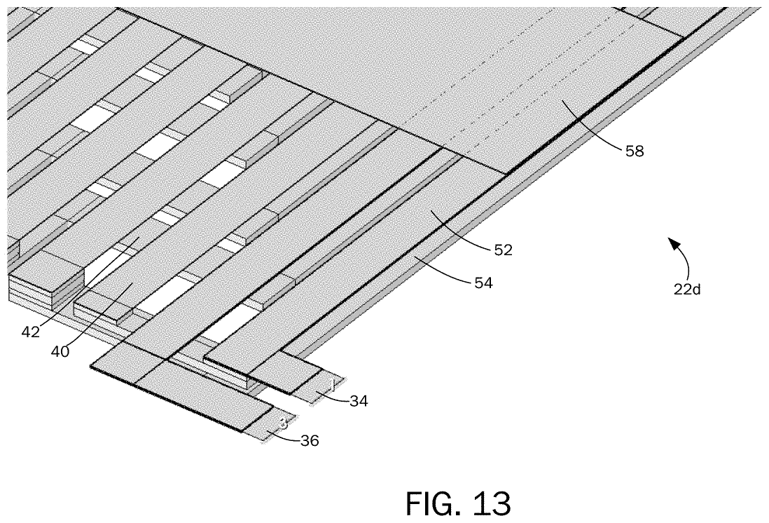

FIG. 13 shows a portion of an alternative fourth embodiment of a 90-degree 3 dB coupler 22d. Like the other three embodiments, there is an input port, an isolated port, a first output port, and the second output port, but only the isolated port 34 and the first output port 36 are shown. The fourth embodiment of the coupler 22d shares much of the same structure as the second and third embodiment of the coupler 22b, 22c, and so for the sake of brevity, the details will be omitted.

Like the earlier discussed embodiments, the coupler 22d includes a plurality of solenoid structures 40 that are arranged in a parallel, spaced relationship, as well as a plurality of interconnects 42. Again, there are multiple groups of interconnects 42 that bridge the solenoid structures 40 of a different sets that define contiguous connections from the input port 32 to the first output port 36 and from the isolated port to the second output port. The solenoid structures 40 may be comprised of the upper thin strip part 52 and a lower thick strip part 54. The fourth embodiment of the coupler 22d also incorporates the capacitively coupled ports.

Although the fourth embodiment of the coupler 22d includes the compensating conductive strip 58, it is disposed above the upper thin strip part 52 of the solenoid structures 40 rather than in the interior space 55 between the thin strip part 52 and the thick strip part 54.

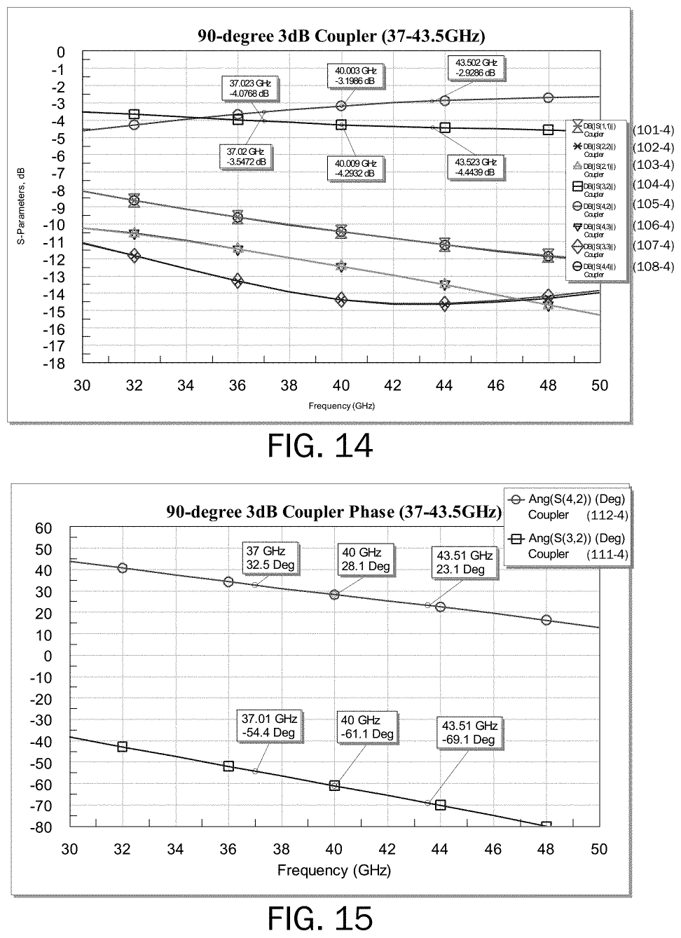

The graphs of FIGS. 14 and 15 illustrate the simulated performance of the fourth embodiment of the coupler 22d. FIG. 14 plots the simulated scattering parameters (S-Parameters) over a frequency sweep between 30 to 50 GHz, with a first plot 101-4 showing the reflection coefficient/return loss S11 at the input port 32, and a second plot 102-4 showing the reflection coefficient S22 at the isolated port 34. A third plot 103-4 shows the insertion loss S21 between the isolated port 34 and the input port 32, and a fourth plot 104-4 the shows the insertion loss S31 between the second output port 38 and the input port 32. Similarly, a fifth plot 105-4 shows the insertion loss S41 between the first output port 36 and the input port 32. A sixth plot 106-4 shows the isolation between the first output port 36 and the second output port 38 (S43). A seventh plot 107-4 shows the output reflection coefficient S33 of the second output port 38, and an eighth plot 108-4 shows the output reflection coefficient S44 of the first output port 36. Given a coupler of identical dimensions to the third embodiment, the placement of the compensating conductive strip 58 above the solenoid structures 40 results in a shift towards lower operating frequency bands.

The graph of FIG. 15 illustrates the simulated phase shift performance of the fourth embodiment of the coupler 22d over the same frequency sweep of 30 to 50 GHz. A first plot 111-4 shows the phase shift that gets applied to the input signal on the input port 32 when output to the first output port 36, and a second plot 112-4 shows the phase shift at the second output port 38.

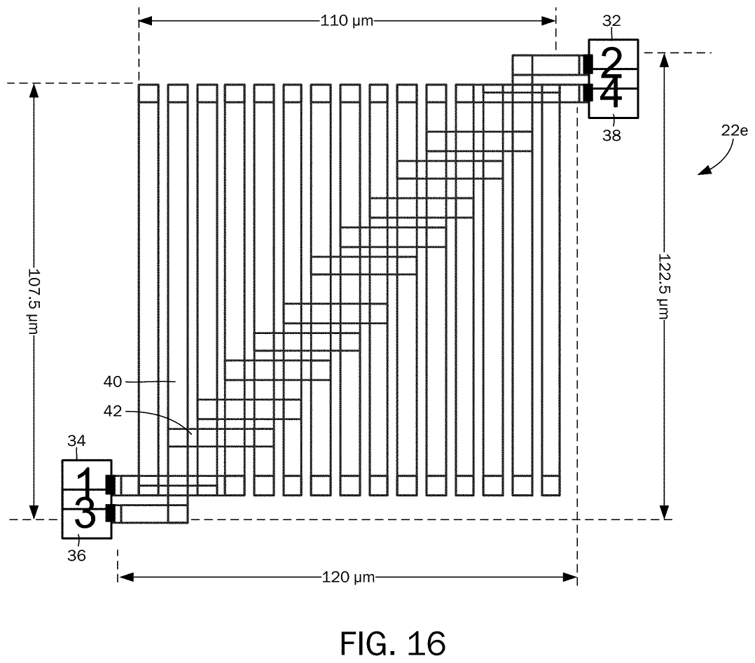

FIG. 16 depicts a fifth embodiment of a 90-degree 3 dB coupler 22e. Like the other four embodiments, there is the input port 32, the isolated port 34, the first output port 36, and the second output port 38. The fifth embodiment of the coupler 22e shares much of the same structure as the second embodiment of the coupler 22b, and so for the sake of brevity, the details will be omitted.

Like the earlier discussed embodiments, the coupler 22e includes a plurality of solenoid structures 40 that are arranged in a parallel, spaced relationship, as well as a plurality of interconnects 42. Again, there are multiple groups of interconnects 42 that bridge the solenoid structures 40 of a different sets that define contiguous connections from the input port 32 to the first output port 36 and from the isolated port to the second output port. The fifth embodiment of the coupler 22e also incorporates the capacitively coupled ports. However, unlike the previously discussed embodiments, the fifth embodiment 22e eliminates the compensating conductive strip 58 altogether.

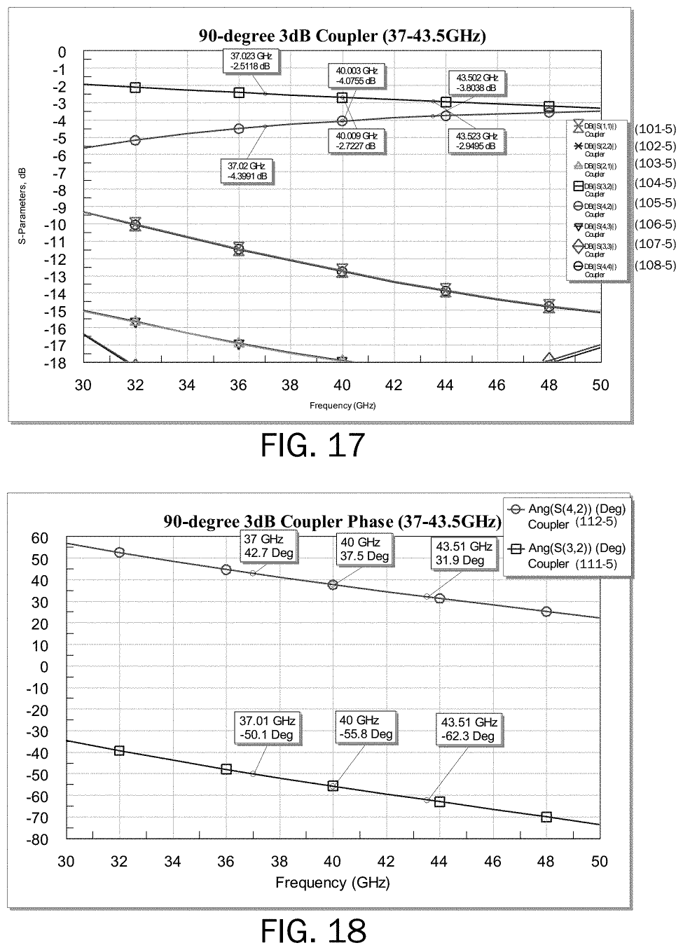

The graphs of FIGS. 17 and 18 illustrate the simulated performance of the fifth embodiment of the coupler 22e. FIG. 17 plots the simulated scattering parameters (S-Parameters) over a frequency sweep between 30 to 50 GHz, with a first plot 101-5 showing the reflection coefficient/return loss S11 at the input port 32, and a second plot 102-5 showing the reflection coefficient S22 at the isolated port 34. A third plot 103-5 shows the insertion loss S21 between the isolated port 34 and the input port 32, and a fourth plot 104-5 the shows the insertion loss S31 between the second output port 38 and the input port 32. Similarly, a fifth plot 105-5 shows the insertion loss S41 between the first output port 36 and the input port 32. A sixth plot 106-5 shows the isolation between the first output port 36 and the second output port 38 (S43). A seventh plot 107-5 shows the output reflection coefficient S33 of the second output port 38, and an eighth plot 108-5 shows the output reflection coefficient S44 of the first output port 36. The absence of the compensating conductive strip is understood to increase the amplitude imbalance at frequencies of interest, but may be used at frequencies above 44 GHz.

The graph of FIG. 15 illustrates the simulated phase shift performance of the fifth embodiment of the coupler 22d over the same frequency sweep of 30 to 50 GHz. A first plot 111-5 shows the phase shift that gets applied to the input signal on the input port 32 when output to the first output port 36, and a second plot 112-5 shows the phase shift at the second output port 38.

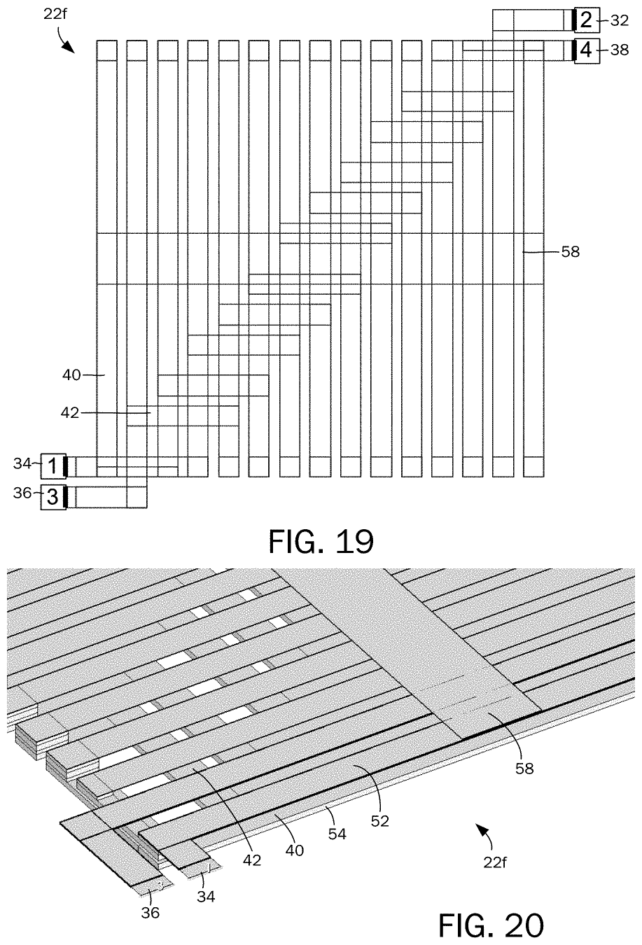

FIGS. 19 and 20 illustrate a sixth embodiment of a 90-degree 3 dB coupler 22f. Like the other five embodiments, there is the input port 32, the isolated port 34, the first output port 36, and the second output port 38. The sixth embodiment of the coupler 22f shares much of the same structure as the fourth embodiment of the coupler 22d, and so for the sake of brevity, the details will be omitted.

Like the earlier discussed embodiments, the coupler 22f includes a plurality of solenoid structures 40 that are arranged in a parallel, spaced relationship, as well as a plurality of interconnects 42. Again, there are multiple groups of interconnects 42 that bridge the solenoid structures 40 of a different sets that define contiguous connections from the input port 32 to the first output port 36 and from the isolated port to the second output port. The solenoid structures 40 may be comprised of the upper thin strip part 52 and a lower thick strip part 54.

In comparison to the fourth embodiment of the coupler 22d considered above, this sixth embodiment 22f incorporates a smaller compensating conductive strip 58. Specifically, the width is 12.5 μm, and is intended to bring the operating frequency band more in line with desired values of 35 to 45 GHz. Like the fourth embodiment, however, the compensating conductive strip 58 is disposed above the upper thin strip part 52 of the solenoid structures 40.

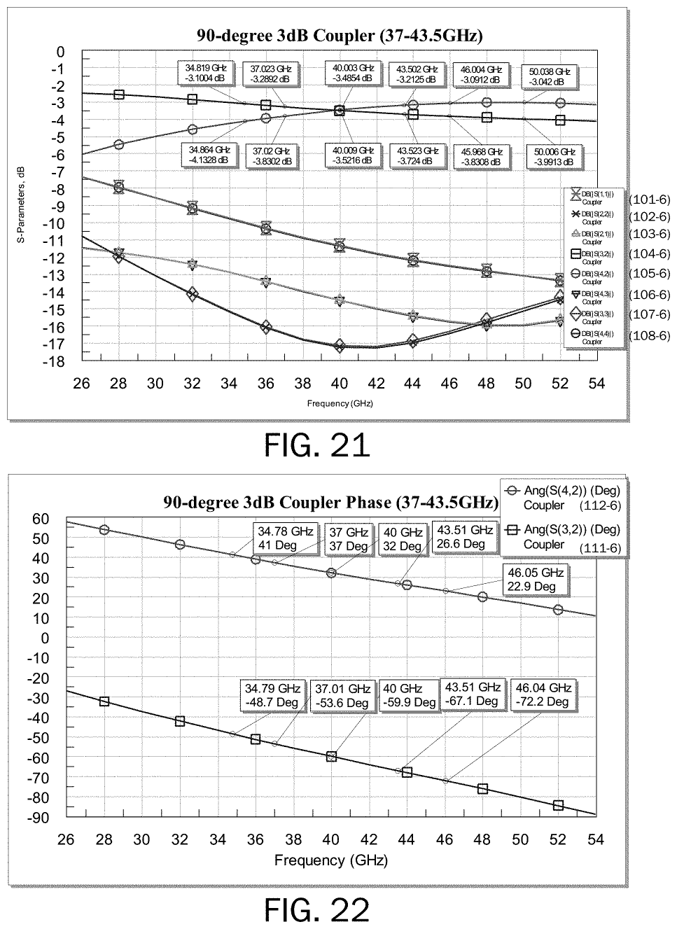

The graphs of FIGS. 21 and 22 illustrate the simulated performance of the sixth embodiment of the coupler 22f. FIG. 21 plots the simulated scattering parameters (S-Parameters) over a frequency sweep between 26 to 54 GHz, with a first plot 101-6 showing the reflection coefficient/return loss S11 at the input port 32, and a second plot 102-6 showing the reflection coefficient S22 at the isolated port 34. A third plot 103-6 shows the insertion loss S21 between the isolated port 34 and the input port 32, and a fourth plot 104-6 the shows the insertion loss S31 between the second output port 38 and the input port 32. Similarly, a fifth plot 105-6 shows the insertion loss S41 between the first output port 36 and the input port 32. A sixth plot 106-6 shows the isolation between the first output port 36 and the second output port 38 (S43). A seventh plot 107-6 shows the output reflection coefficient S33 of the second output port 38, and an eighth plot 108-6 shows the output reflection coefficient S44 of the first output port 36.

The graph of FIG. 22 illustrates the simulated phase shift performance of the sixth embodiment of the coupler 22d over the same frequency sweep of 26 to 54 GHz. A first plot 111-6 shows the phase shift that gets applied to the input signal on the input port 32 when output to the first output port 36, and a second plot 112-6 shows the phase shift at the second output port 38.

The following table 4 summarizes the simulated difference in output signal power from the first output port 36 and the second output port 38, as well as the output signal phase from the same, across selected operating frequencies. Furthermore, the average power loss at either of the output ports 36, 38 for each of the selected operating frequencies are presented. As can be seen, the compensating conductive strip 58 can be adjusted to greatly improve amplitude imbalance.

TABLE 4

| F (GHz) | 34.8 GHz | 37 GHz | 40 GHz | 43.5 GHz | 46 GHz |
|---|---|---|---|---|---|
| Delta OUT, dB | 1.0 | 0.54 | 0.04 | 0.51 | 0.74 |
| Delta Angle, | 89.7 | 90.6 | 91.9 | 93.7 | 95.1 |
| degree | | | | | |
| Average Loss, dB | 3.62 | 3.56 | 3.5 | 3.47 | 3.46 |

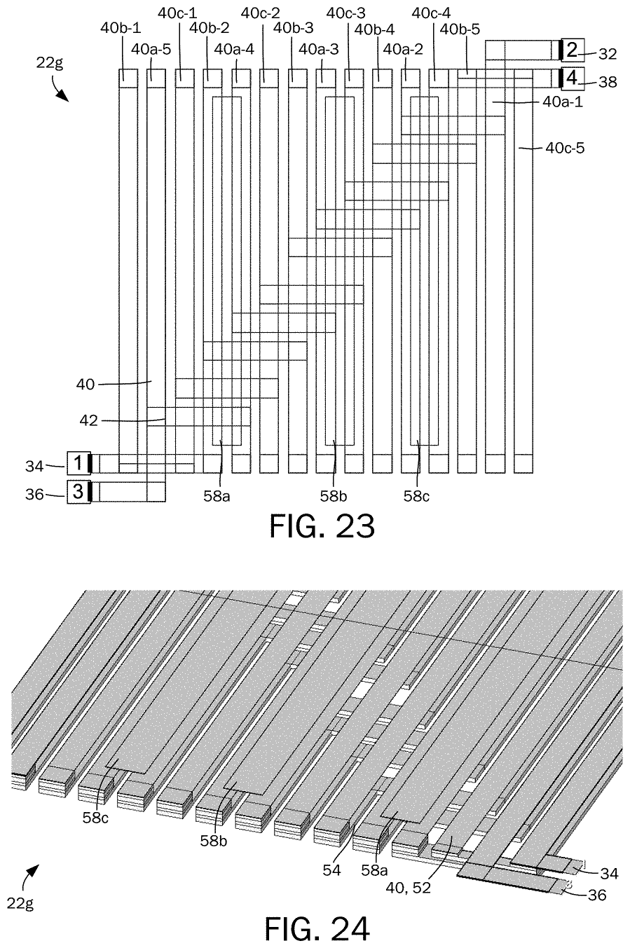

FIGS. 23 and 24 illustrate a seventh embodiment of a 90-degree 3 dB coupler 22g. Like the other five embodiments, there is the input port 32, the isolated port 34, the first output port 36, and the second output port 38. The seventh embodiment of the coupler 22g shares much of the same structure as the fourth as well as the sixth embodiment of the coupler 22d, and so for the sake of brevity, the details will be omitted.

The coupler 22g includes a plurality of solenoid structures 40 that are arranged in a parallel, spaced relationship, as well as a plurality of interconnects 42. Again, there are multiple groups of interconnects 42 that bridge the solenoid structures 40 of a different sets that define contiguous connections from the input port 32 to the first output port 36 and from the isolated port to the second output port 38. The solenoid structures 40 may be comprised of the upper thin strip part 52 and a lower thick strip part 54.

The seventh embodiment of the coupler 22g incorporates multiple compensating conductive strips 58 that are vertically oriented in alignment with the solenoid structures 40. Specifically, there is a first vertically oriented compensating conductive strip 58a positioned in an overlapping relationship with the second solenoid structure 40b-2 of the second set and the fourth solenoid structure 40a-4 of the first set. There is also a second vertically oriented compensating conductive strip 58b positioned in an overlapping relationship with the third solenoid structure 40a-3 of the first set and the third solenoid structure 40c-3 of the third set. Further, there is a third vertically oriented compensating conductive strip 58c positioned in an overlapping relationship with the second solenoid structure 40a-2 of the first set, and the fourth solenoid structure 40c-4 of the third set. The vertically oriented compensating conductive strips 58a-58c may each have a width of 7.5 μm according to an embodiment of the present disclosure. This configuration is in contrast to the horizontally oriented, single compensating conductive strip 58 of the other embodiments.

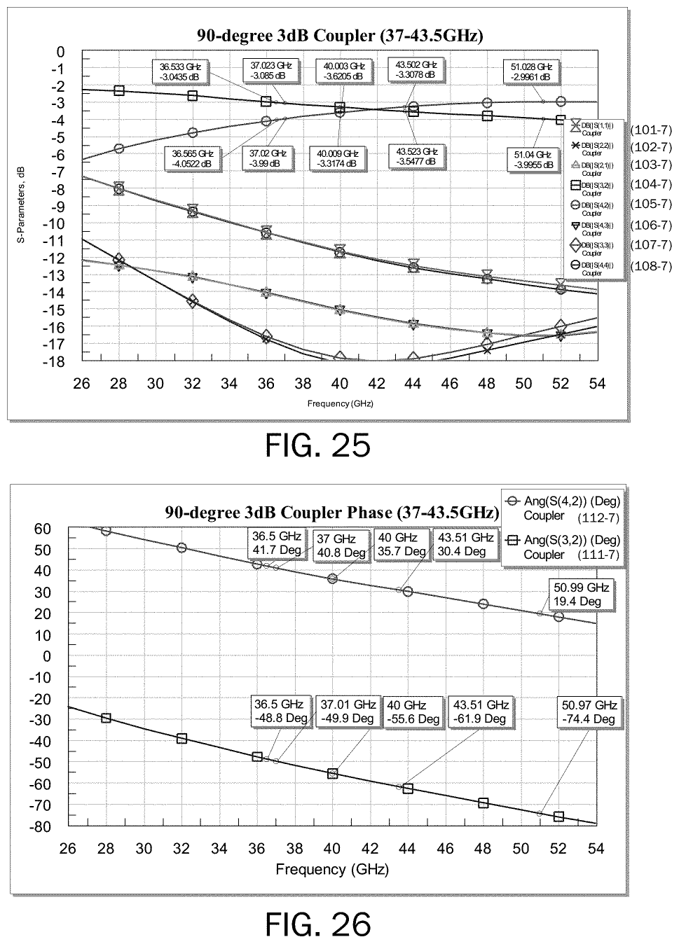

The graphs of FIGS. 25 and 26 illustrate the simulated performance of the seventh embodiment of the coupler 22g. FIG. 25 plots the simulated scattering parameters (S-Parameters) over a frequency sweep between 26 to 54 GHz, with a first plot 101-7 showing the reflection coefficient/return loss S11 at the input port 32, and a second plot 102-7 showing the reflection coefficient S22 at the isolated port 34. A third plot 103-7 shows the insertion loss S21 between the isolated port 34 and the input port 32, and a fourth plot 104-7 the shows the insertion loss S31 between the second output port 38 and the input port 32. Similarly, a fifth plot 105-7 shows the insertion loss S41 between the first output port 36 and the input port 32. A sixth plot 106-7 shows the isolation between the first output port 36 and the second output port 38 (S43). A seventh plot 107-7 shows the output reflection coefficient S33 of the second output port 38, and an eighth plot 108-7 shows the output reflection coefficient S44 of the first output port 36.

The graph of FIG. 26 illustrates the simulated phase shift performance of the seventh embodiment of the coupler 22g over the same frequency sweep of 26 to 54 GHz. A first plot 111-7 shows the phase shift that gets applied to the input signal on the input port 32 when output to the first output port 36, and a second plot 112-7 shows the phase shift at the second output port 38.

The following table 5 summarizes the simulated difference in output signal power from the first output port 36 and the second output port 38, as well as the output signal phase from the same, across selected operating frequencies. Furthermore, the average power loss at either of the output ports 36, 38 for each of the selected operating frequencies are presented.

TABLE 5

| F (GHz) | 34.8 GHz | 37 GHz | 40 GHz | 43.5 GHz | 46 GHz |
|---|---|---|---|---|---|
| Delta OUT, dB | 1.0 | 0.91 | 0.3 | 0.24 | 1.0 |
| Delta Angle, | 90.5 | 90.6 | 91.9 | 93.7 | 93.8 |
| degree | | | | | |
| Average Loss, dB | 3.55 | 3.54 | 3.47 | 3.43 | 3.5 |

The particulars shown herein are by way of example and for purposes of illustrative discussion of the embodiments of the present disclosure only and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A coupler with an input port, an isolated port, a first output port, and a second output port, comprising:
a plurality of solenoid structures arranged in a parallel, spaced relationship; and
a plurality of interconnects, a first group of the interconnects bridging the solenoid structures of a first set that define a first contiguous connection from the input port to the first output port, a second group of interconnects bridging the solenoid structures of a second set that define a second contiguous connection from the isolated port to the second output port, and a third group of interconnects bridging the solenoid structures of a third set that define a third contiguous connection from the isolated port to the second output port, the solenoid structures each being unique to a respective one of the first set, second set, and the third set.

2. The coupler of claim 1, wherein adjacent ones of the solenoid structures are of different first, second and third sets thereof.

3. The coupler of claim 1, wherein adjacent ones of the interconnects are of different first, second, and third groups thereof.

4. The coupler of claim 1, wherein the solenoid structures are each defined by a thin strip part and a thick strip part, the thin strip part and the thick strip part being parallel to and vertically spaced apart from each other, opposing ends of the thin strip part and the thick strip part of a given one of the solenoid structures are connected to each other with corresponding vias.

5. The coupler of claim 4, wherein the interconnects are coplanar with the thick strip part of the solenoid structures to which it is connected.

6. The coupler of claim 4, wherein:
the thick strip part of the solenoid structures are implemented on an AP layer of a semiconductor die; and
the thin strip part of the solenoid structures are implemented on an M6 layer of the semiconductor die.

7. The coupler of claim 1, further comprising:
an input port connector strip between the input port and a corresponding one of the solenoid structures connected thereto;
an first output port connector strip between the output port and a corresponding one of the solenoid structures connected thereto;
an isolated port connector strip between the isolated port and corresponding ones of the solenoid structures connected thereto; and
a second output port connector strip between the output port and corresponding ones of the solenoid structures connected thereto.

8. The coupler of claim 1, further comprising:
a lateral compensating conductive strip extending across the plurality of solenoid structures.

9. The coupler of claim 8, wherein the lateral compensating conductive strip has a width of approximately 22.5 μm.

10. The coupler of claim 8, wherein a width of the lateral compensating conductive strip is tuned to a predetermined operating frequency band.

11. The coupler of claim 10, wherein the width of the lateral compensating conductive strip is approximately 12.5 μm.

12. The coupler of claim 8, wherein:
the solenoid structures are each defined by a thin strip part and a thick strip part, the thin strip part and the thick strip part being parallel to and vertically spaced apart from each other; and
the lateral compensating conductive strip is positioned between the thin strip parts and the thick strip parts of the solenoid structures.

13. The coupler of claim 8, further comprising:
a capacitively coupled input port connector between the input port and a corresponding one of the solenoid structures connected thereto;
a capacitively coupled first output port connector between the output port and a corresponding one of the solenoid structures connected thereto;
a capacitively coupled isolated port connector between the isolated port and corresponding ones of the solenoid structures connected thereto; and
a capacitively coupled second output port connector between the output port and corresponding ones of the solenoid structures connected thereto.

14. The coupler of claim 11, wherein each of the capacitively coupled input port connector, capacitively coupled first output port, capacitively coupled isolated port connector, and capacitively coupled second output port connector is defined by a first layer and a second layer vertically adjacent thereto, the solenoid structures being implemented on a third layer vertically separated from the first layer and the second layer.

15. The coupler of claim 12, wherein the first layer is an M5 metal layer of a semiconductor die, the second layer is an M4 metal layer of the semiconductor die, and the third layer is an M6 layer of the semiconductor die.

16. The coupler of claim 8, wherein the lateral compensating conductive strip is disposed in a different layer above the solenoid structures.

17. The coupler of claim 1, further comprising:
a capacitively coupled input port connector between the input port and a corresponding one of the solenoid structures connected thereto;
a capacitively coupled first output port connector between the output port and a corresponding one of the solenoid structures connected thereto;
a capacitively coupled isolated port connector between the isolated port and corresponding ones of the solenoid structures connected thereto; and
a capacitively coupled second output port connector between the output port and corresponding ones of the solenoid structures connected thereto.

18. The coupler of claim 1, further comprising:
one or more vertically oriented compensating conductive strips placed in an overlapping relationship with the solenoid structures, the vertically oriented compensating conductive strips being in axial alignment with the solenoid structures.

19. The coupler of claim 18, wherein:
a first one of the vertically oriented compensating conductive strips overlaps one of the solenoid structures of the first set and of the second set;
a second one of the vertically oriented compensating conductive strips overlaps one of the solenoid structures of the second set and of the third set; and
a third one of the vertically oriented compensating conductive strips overlaps one of the solenoid structures of the first set and of the third set.

20. The coupler of claim 18, wherein a width of one of the vertically oriented compensating conductive strips is approximately 7.5 μm.
